(19) United States
(12) Patent Application Publication
(10) Pub. No.: US 2024/0332006 A1
(43) Pub. Date: Oct. 3, 2024

(54) METHODS TO IMPROVE QUALITY SILICON-CONTAINING MATERIALS

(71) Applicant: Applied Materials, Inc., Santa Clara, CA (US)

(72) Inventors: Tianyang Li, San Jose, CA (US); Jisung Park, Sunnyvale, CA (US); Xinhai Han, Palo Alto, CA (US); Woongsik Nam, Santa Clara, CA (US); Deenesh Padhi, Saratoga, CA (US)

(73) Assignee: Applied Materials, Inc., Santa Clara, CA (US)

(21) Appl. No.: 18/192,557

(22) Filed: Mar. 29, 2023

(51) Int. Cl. H01L 21/02; H01L 21/324

(52) U.S. Cl. CPC H01L 21/02274; H01L 21/02164; H01L 21/02214; H01L 21/02236; H01L 21/324

(57) ABSTRACT

Exemplary methods of forming a silicon-and-carbon-containing material may include providing a silicon-containing precursor to a processing region of a semiconductor processing chamber. A substrate may be housed within the processing region of the semiconductor processing chamber. The methods may include providing a hydrogen-containing precursor to the processing region. The methods may include generating plasma effluents of the silicon-containing precursor and plasma effluents of the hydrogen-containing precursor in the processing region. The plasma effluents may be generated at a frequency greater than 15 MHz. The methods may include depositing a silicon-containing material on the substrate.

### TECHNICAL FIELD

The present technology relates to deposition processes and chambers. More specifically, the present technology relates to methods of producing silicon-containing materials with increased film quality.

### BACKGROUND

Integrated circuits are made possible by processes which produce intricately patterned material layers on substrate surfaces. Producing patterned material on a substrate requires controlled methods for forming and removing material. Material characteristics may affect how the device operates, and may also affect how the films are removed relative to one another. Plasma-enhanced deposition may produce films having certain characteristics. Many films that are formed require additional processing to adjust or enhance the material characteristics of the film in order to provide suitable properties.

Thus, there is a need for improved systems and methods that can be used to produce high quality devices and structures. These and other needs are addressed by the present technology.

### SUMMARY

Exemplary methods of forming a silicon-and-carbon-containing material may include providing a silicon-containing precursor to a processing region of a semiconductor processing chamber. A substrate may be housed within the processing region of the semiconductor processing chamber. The methods may include providing a hydrogen-containing precursor to the processing region. The methods may include generating plasma effluents of the silicon-containing precursor and plasma effluents of the hydrogen-containing precursor in the processing region. The plasma effluents may be generated at a frequency greater than 15 MHZ. The methods may include depositing a silicon-containing material on the substrate.

In some embodiments, the silicon-containing precursor may be or include tetracthyl orthosilicate (TEOS). The hydrogen-containing precursor may be less than or about 5% of a total flow of precursors provided to the processing region. A plasma power may be maintained at less than or about 1000 W while generating plasma effluents of the silicon-containing precursor and plasma effluents of the hydrogen-containing precursor. A temperature in the semiconductor processing chamber may be maintained at less than or about 600° C. during the method. A pressure in the semiconductor processing chamber may be maintained at less than or about 30 Torr during the method. The methods may include performing a post-deposition treatment on the silicon-containing material. Performing the post-deposition treatment may increase an oxygen content in the silicon-containing material. The post-deposition treatment may include exposing the silicon-containing material to ultraviolet light. The post-deposition treatment may include annealing the silicon-containing material in the presence of a second hydrogen-containing precursor, a nitrogen-containing precursor, or an oxygen-containing precursor.

Some embodiments of the present technology encompass semiconductor processing methods. The methods may include providing a silicon-containing precursor to a processing region of a semiconductor processing chamber. A substrate may be housed within the processing region of the semiconductor processing chamber. The methods may include generating plasma effluents of the silicon-containing precursor in the processing region. The methods may include depositing a silicon-containing material on the substrate. The methods may include performing a post-deposition treatment on the silicon-containing material. Performing the post-deposition treatment increases an oxygen content in the silicon-containing material.

In some embodiments, the substrate may define one or more features. The plasma effluents may be generated at a frequency greater than 15 MHZ. The methods may include providing a hydrogen-containing precursor to the processing region. The hydrogen-containing precursor may be or include molecular hydrogen (H₂). The post-deposition treatment may include exposing the silicon-containing material to ultraviolet light in the presence of an inert precursor or an oxygen-containing precursor. The post-deposition treatment may include annealing the silicon-containing material at a temperature less than or about 600° C.

Some embodiments of the present technology encompass semiconductor processing methods. The methods may include providing a silicon-containing precursor to a processing region of a semiconductor processing chamber. A substrate may be housed within the processing region of the semiconductor processing chamber. The methods may include providing a hydrogen-containing precursor to the processing region. The methods may include generating plasma effluents of the silicon-containing precursor and plasma effluents of the hydrogen-containing precursor in the processing region. The plasma effluents may be generated at a frequency greater than 15 MHz. The methods may include depositing a silicon-containing material on the substrate. The methods may include performing a post-deposition treatment on the silicon-containing material. Performing the post-deposition treatment may increase an oxygen content in the silicon-containing material.

In some embodiments, performing the post-deposition treatment may decrease a hydrogen content in the silicon-containing material. The methods may include halting a flow of the silicon-containing precursor and a flow of the hydrogen-containing precursor prior to performing the post-deposition treatment.

Such technology may provide numerous benefits over conventional systems and techniques. For example, utilizing higher frequency power may improve silicon-containing material deposition characteristics. Additionally, performing a post-deposition treatment on the deposited silicon-containing material may further increase quality of the silicon-containing material. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows operations of an exemplary semiconductor processing method according to some embodiments of the present technology.

FIGS. 4A-4B show exemplary schematic cross-sectional structures in which material layers are included and produced according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

During semiconductor processing, materials may be deposited for gapfill operations, such as for staircase fill in 3D NAND applications. These materials may be deposited through plasma-enhanced chemical vapor deposition (PECVD). As device sizes continue to shrink, plasma characteristics may not be able to deposit materials, such as silicon-containing materials, with high enough quality such as at sidewalls of the features being filled. Deposited materials with poorer than desired quality may be less resistant to etch operations than material deposited in the middle of the features being filled. The poorer quality material at the sidewalls may be etched faster than other materials, resulting in uneven material across the feature previously filled.

The present technology may overcome these issues by providing silicon-containing materials that, as-deposited or as treated after deposition, may be characterized by higher quality. By performing deposition at higher plasma frequency, sidewall material quality may be increased. Additionally, by including a hydrogen-containing precursor in the deposition, film interactions may produce a high-quality silicon-containing material, especially at sidewalls. The present technology also includes post-deposition operations to further modify the deposited film. The post-deposition operations may also reorganize the structure of the deposited silicon-containing material. For example, the post-deposition operations may reorganize bonds in the material to provide a higher quality material. Th present technology may overcome the natural tendency of the material deposited at the sidewalls to be poorer quality than the material deposited closer to the middle of the features.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered to be so limited as for use with these specific deposition processes or chambers alone. The disclosure will discuss one possible system and chamber that may be used to perform deposition processes according to embodiments of the present technology before additional details according to embodiments of the present technology are described.

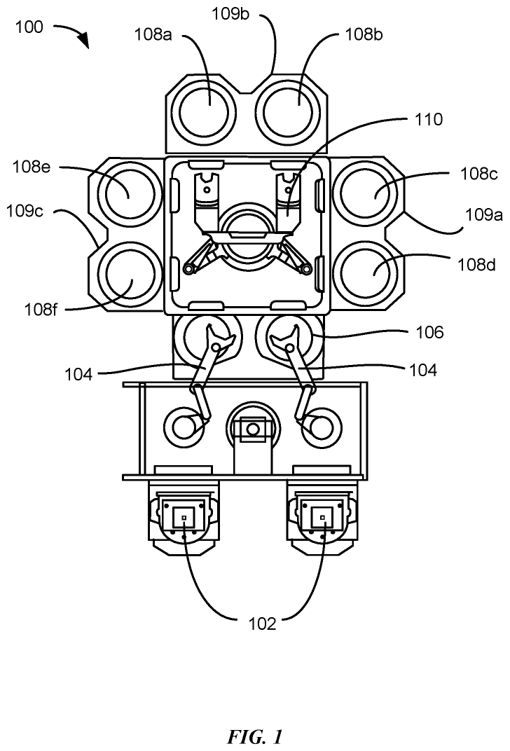

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition (PECVD), atomic layer deposition (ALD), physical vapor deposition (PVD), etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

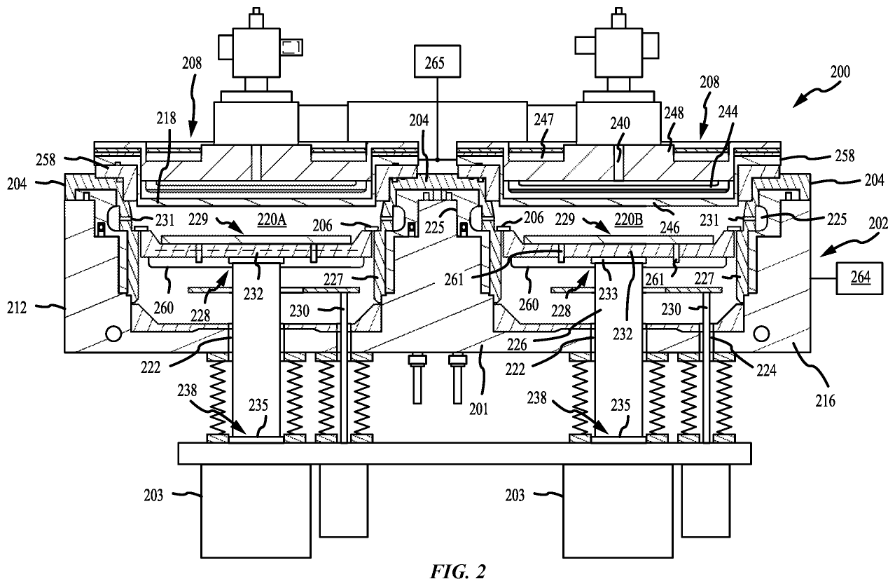

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include lid stack components according to embodiments of the present technology, and as may be explained further below. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a dual-channel showerhead 218 into the processing region 220B. The dual-channel showerhead 218 may include an annular base plate 248 having a blocker plate 244 disposed intermediate to a faceplate 246. A radio frequency (“RF”) source 265 may be coupled with the dual-channel showerhead 218, which may power the dual-channel showerhead 218 to facilitate generating a plasma region between the faceplate 246 of the dual-channel showerhead 218 and the pedestal 228. The dual-channel showerhead 218 and/or faceplate 246 may include one or more openings to permit the flow of precursors from the precursor distribution system 208 to the processing regions 220A and/or 220B. In some embodiments, the openings may include at least one of straight-shaped openings and conical-shaped openings. In some embodiments, the RF source may be coupled with other portions of the chamber body 202, such as the pedestal 228, to facilitate plasma generation. A dielectric isolator 258 may be disposed between the lid 204 and the dual-channel showerhead 218 to prevent conducting RF power to the lid 204. A shadow ring 206 may be disposed on the periphery of the pedestal 228 that engages the pedestal 228.

An optional cooling channel 247 may be formed in the annular base plate 248 of the precursor distribution system 208 to cool the annular base plate 248 during operation. A heat transfer fluid, such as water, ethylene glycol, a gas, or the like, may be circulated through the cooling channel 247 such that the base plate 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

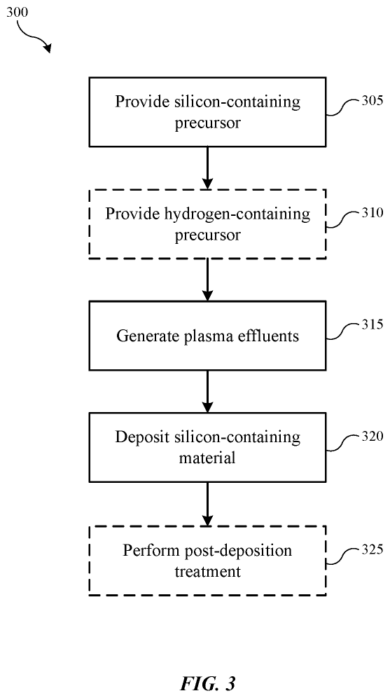

FIG. 3 shows exemplary operations of a semiconductor processing method 300 according to some embodiments of the present technology. The method 300 may be performed in a variety of processing chambers, including processing system 200 described above, as well as in any other chamber in which the operations may be performed. Method 300 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

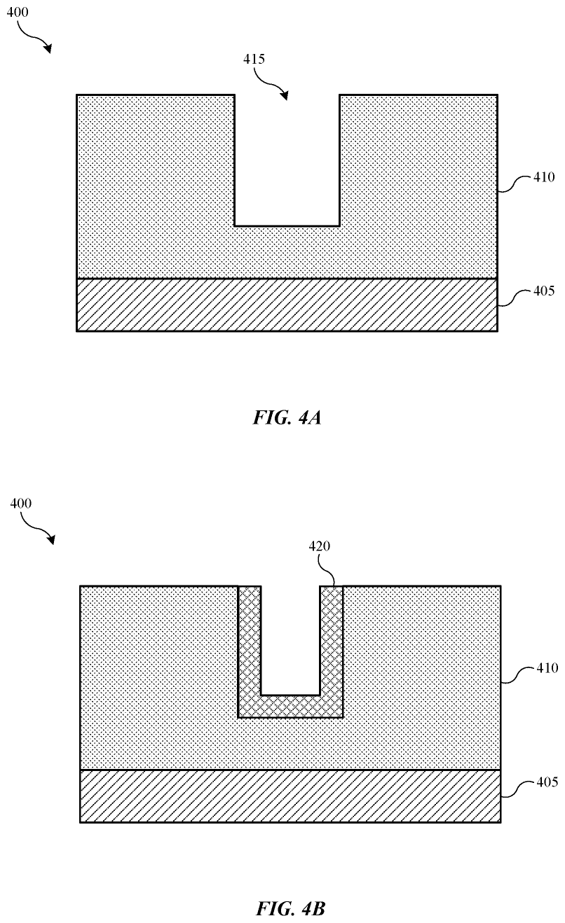

Method 300 may include additional operations prior to initiation of the listed operations. For example, additional processing operations may include forming structures on a semiconductor substrate, which may include both forming and removing material. Prior processing operations may be performed in the chamber in which method 300 may be performed, or processing may be performed in one or more other processing chambers prior to delivering the substrate into the semiconductor processing chamber in which method 300 may be performed. Regardless, method 300 may optionally include delivering a semiconductor substrate to a processing region of a semiconductor processing chamber, such as processing chamber 200 described above, or other chambers that may include components as described above. The substrate may be positioned on a substrate support, such as pedestal 228, and which may reside in a processing region of the chamber, such as processing region 220 described above. Method 300 describes operations shown schematically in FIGS. 4A-4B, the illustrations of which will be described in conjunction with the operations of method 300. It is to be understood that FIGS. 4A-4B illustrate only partial schematic views of an exemplary structure 400, and a substrate 405 may contain any number of additional materials and features having a variety of characteristics and aspects as illustrated in the figures.

As shown in FIG. 4A, the substrate 405 may be any number of materials on which deposition may be performed. The substrate 405 may be or include silicon, germanium, dielectric materials including silicon oxide or silicon nitride, metal materials, or any number of combinations of these materials, which may be the substrate, or materials formed on the substrate. A number of materials may be formed over the substrate 405. For example, a material 410 may be formed over the substrate 405. As depicted, the material 410 may include a feature 415. The aspect ratio of the feature 410, or the ratio of the depth of the feature relative to the width or diameter of the feature formed, may be greater than or about 1:1, and may be greater than or about 2:1, than or about 3:1, greater than or about 4:1, greater than or about 5:1, greater than or about 6:1, greater than or about 7:1, greater than or about 8:1, greater than or about 9:1, greater than or about 10:1, or more. Although only one feature 410 is shown, it is to be understood that exemplary structures may have any number of features 410 defined along the structure according to embodiments of the present technology. In embodiments, structure 400 may be a 3D NAND structure.

Method 300 may include deposition processing operations, such as PECVD operations, to form silicon-containing materials on substrates with increased material quality specifically on sidewalls of the features. Method 300, as shown in FIG. 3, may include flowing one or more precursors into the semiconductor processing chamber at operation 305, which may deliver the precursor or precursors into a processing region of the semiconductor processing chamber where a substrate, such as substrate 405, may be housed, for example.

In embodiments, the precursor delivered at operation 305 may be or include a silicon-containing precursor. Silicon-containing precursors that may be used in operation 305 of method 300 may be or include any number of silicon-containing precursors. For example, the silicon-containing precursor may be or include silane (SiH₄), disilane (Si₂H₆), trisilane (Si₃H₈), silicon tetrachloride (SiCl₄), tetraethyl orthosilicate (TEOS), or any other precursor able to form a silicon-containing material such as, for example, a silicon oxide (SiO) material. Although higher-order silanes may be used in embodiments of the present technology, the increased hydrogen content in the material as deposited may lead to outgassing in subsequent operations.

At optional operation 310, method 300 may include providing a hydrogen-containing precursor to the processing region. In embodiments, the hydrogen-containing precursor may be provided with the silicon-containing precursor. The hydrogen-containing precursor and the silicon-containing precursor may be mixed prior to being provided to the processing region. However, it is contemplated that the hydrogen-containing precursor and the silicon-containing precursor may be kept isolated prior to being provided to the processing region. Hydrogen-containing precursors that may be used in optional operation 310 of method 300 may be or include any number of hydrogen-containing precursors. For example, the hydrogen-containing precursor may be or include molecular hydrogen (H₂), steam (H₂O), or any other precursor useful in forming a silicon-containing material such as, for example, a silicon oxide (SiO) material.

The precursors provided at operations 305 and/or 310 may also include any number of carrier gases, which may include nitrogen, helium, argon, or other noble, inert, or useful precursors. The carrier gases may be used to dilute the silicon-containing precursor or the hydrogen-containing precursor, which may reduce deposition rates to allow adequate control of the deposition. However, it is contemplated that the precursors may be provided without any other gases.

In embodiments, a flow rate of the hydrogen-containing precursor may impact the deposition of silicon-containing material. Higher flow rates of the hydrogen-containing precursor may incorporate additional hydrogen in the deposited material, which as previously discussed may lead to outgassing in subsequent operations. Accordingly, the hydrogen-containing precursor may make up less than or about 5% of a total flow of precursors provided to the processing region, such as less than or about 4.5% of the total flow of precursors, less than or about 4%, less than or about 3.5%, less than or about 3%, less than or about 2.5%, less than or about 2%, less than or about 1.5%, less than or about 1%, or less. By providing the hydrogen-containing precursor at operation 310, the energy of a subsequently formed plasma discussed below may increase. Additionally, the hydrogen may readily travel through the deposited material and may remove dangling bonds from the material. The removal of dangling bonds a may allow for increased Si—O bonding and, therefore, higher quality silicon-containing material to remain on the substrate 405.

The precursors delivered to the processing region, such as the silicon-containing precursor and the hydrogen-containing precursor, may be used to generate a plasma within the processing region of the semiconductor processing chamber at operation 315 of method 300. The plasma may be generated by, for example, providing RF power to the faceplate to generate a plasma within processing region 220, although any other processing chamber capable of producing plasma may similarly be used. In embodiments, the plasma may be generated at a frequency greater than or about 15 MHZ. Although lower frequency may be used, in some embodiments the higher frequency plasma generation may densify the plasma and, therefore, densify the deposited material, unlike lower plasma frequency operations. Accordingly, the plasma may be generated at a frequency greater than or about 17 MHZ, greater than or about 19 MHz, greater than or about 21 MHZ, greater than or about 23 MHZ, greater than or about 25 MHz, greater than or about 27 MHz, or higher.

Additionally, a plasma power may be maintained at less than or about 1000 W while generating plasma effluents of the silicon-containing precursor and plasma effluents of the hydrogen-containing precursor. Accordingly, the plasma power may be maintained at less than or about 900 W, less than or about 800 W, less than or about 700 W, less than or about 600 W, less than or about 500 W, less than or about 450 W, less than or about 400 W, less than or about 350 W, less than or about 300 W, less than or about 250 W, less than or about 200 W, less than or about 150 W, less than or about 100 W, or less.

As shown in FIG. 4B, at operation 320, method 300 may include depositing a silicon-containing material 420 on the substrate 405. The silicon-containing material 420 may be deposited conformally on the substrate 405, such as in the feature 415. In some embodiments, the deposition rate may exceed 500 Å/min, and may exceed greater than or about 700 Å/min, greater than or about 1,000 Å/min, greater than or about 1,200 Å/min, greater than or about 1,400 Å/min, greater than or about 1,600 Å/min, greater than or about 1,800 Å/min, greater than or about 2,000 Å/min. By incorporating a hydrogen-containing precursor in some embodiments, additional energy may be added to the generated plasma. Additionally, the hydrogen plasma effluents may readily travel through the silicon-containing material 420 and remove dangling bonds from the silicon-containing material 420. The removal of dangling bonds from the silicon-containing material 420 may allow for more Si—O bonds to form, increasing the quality of the silicon-containing material 420 especially at the sidewalls of the feature 415. In some embodiments, a high frequency plasma (e.g., greater than 15 MHZ) may densify the plasma effluents. The increased densify of the plasma effluents may also remove dangling bonds from the silicon-containing material 420, allowing for the formation of additional Si—O bonds.

In embodiments, the semiconductor processing chamber, the pedestal, or the substrate 405 may be maintained at a temperature greater than or about 250° C., and in some embodiments may be maintained at a temperature that is greater than or about 300° C., greater than or about 320° C., greater than or about 340° C., greater than or about 360° C., greater than or about 380° C. greater than or about 400° C., greater than or about 420° C., greater than or about 440° C., greater than or about 460° C., greater than or about 480° C., greater than or about 500° C., greater than or about 520° C., greater than or about 540° C., greater than or about 560° C., greater than or about 580° C., or more. Higher temperatures may result in a higher quality silicon-containing material 420 being deposited with increased Si—O bond formation. However, thermal budget constraints may require the semiconductor processing chamber, the pedestal, or the substrate 405 to be maintained at lower temperatures. Accordingly, in some embodiments, the semiconductor processing chamber, the pedestal, or the substrate 305 may be maintained at a temperature less than or about 600° C., and in some embodiments may be maintained at a temperature that is less than or about 580° C., less than or about 560° C., less than or about 540° C., less than or about 520° C., less than or about 500° C., or less.

During the deposition of the silicon-containing material 420, the semiconductor processing chamber may be maintained at any pressure suitable for forming silicon-containing material. For example, a pressure within the semiconductor processing chamber is maintained at less than or about 30 Torr, and in some embodiments may be maintained at a pressure that is less than or about 28 Torr, less than or about 26 Torr, less than or about 24 Torr, less than or about 22 Torr, less than or about 20 Torr, less than or about 18 Torr, less than or about 16 Torr, less than or about 14 Torr, less than or about 12 Torr, less than or about 10 Torr, less than or about 8 Torr, less than or about 6 Torr, less than or about 4 Torr, less than or about 2 Torr, or less.

While a post-deposition treatment may not be necessary to increase quality of the silicon-containing material 420, some embodiments of method 300 may include performing a post-deposition treatment on the silicon-containing material 420 at optional operation 325 after deposition to a sufficient thickness. In embodiments, method 300 may include halting a flow of the silicon-containing precursor and/or a flow of the hydrogen-containing precursor prior to performing the post-deposition treatment. The post-deposition treatment may be any operation to increase the quality of the silicon-containing material 420. For example, the post-deposition treatment may increase an oxygen content in the silicon-containing material 420 and/or decreases a hydrogen content in the silicon-containing material 420.

For example, the post-deposition treatment may include exposing the silicon-containing material 420 to ultraviolet (UV) light. In some embodiments, the exposure to UV light may be performed in the semiconductor processing chamber used for the deposition of the silicon-containing material 420. In additional embodiments, the substrate 405 with the silicon-containing material 420 may be transferred to another semiconductor processing chamber where the UV light exposure operation is performed. The exposure to UV light may be performed in the presence of an oxygen-containing precursor or an inert precursor. For example, the oxygen-containing precursor may be any oxygen-containing material such as, for example, molecular oxygen (O₂) or ozone (O₃). The inert precursor may be any inert material such as, for example, argon, helium, or xenon.

In other embodiments, the post-deposition treatment may include annealing the silicon-containing material 420 on the substrate 405. In some embodiments, the annealing may be performed in the semiconductor processing chamber used for the deposition of the silicon-containing material 420. In additional embodiments, the substrate 405 with the silicon-containing material 420 may be transferred to another semiconductor processing chamber where the annealing is performed. The annealing may be performed in the presence of a hydrogen-containing precursor, a nitrogen-containing precursor, or an oxygen-containing precursor. The hydrogen-containing precursor may be any hydrogen-containing material such as, for example, molecular hydrogen (H₂). The nitrogen-containing precursor may be any nitrogen-containing material such as, for example, molecular nitrogen (N₂). The oxygen-containing precursor may be any oxygen-containing material such as, for example, molecular oxygen (O₂) or ozone (O₃).

Annealing the silicon-containing material 420 on the substrate 405 may result in outgassing of hydrogen and/or carbon from the silicon-containing material 420. For example, when annealing the silicon-containing material 420 in the presence of the oxygen-containing precursor, steam (H₂O) and/or carbon dioxide (CO₂) may outgas from the silicon-containing material 420. Additionally, when annealing the silicon-containing material 420 in the presence of the oxygen-containing precursor, additional oxygen may be imparted to the silicon-containing material, allowing for additional Si—O bonding. Similarly, when annealing the silicon-containing material 420 in the presence of the hydrogen-containing precursor, terminal hydroxyl (—OH) bonds by break from the silicon-containing material 420. The terminal-OH bonds may combine with the hydrogen-containing precursor and outgas as steam (H₂O).

The post-deposition treatment at optional operation 325 may continue for a period of time sufficient to improve quality of the silicon-containing material 420, such as the material on the sidewalls of the feature 410. In embodiments, the period of time may be less than or about 30 minutes, and may be less than or about 28 minutes, less than or about 26 minutes, less than or about 24 minutes, less than or about 22 minutes, less than or about 20 minutes, less than or about 18 minutes, less than or about 16 minutes, less than or about 14 minutes, less than or about 12 minutes, less than or about 10 minutes, or less. Compared with conventional methods to improve sidewall film quality, the post-deposition treatments of the present technology may more readily interact with and treat the deposited silicon-containing material 420.

The post-deposition treatments of the present technology, unlike conventional methods to improve sidewall film quality, may sufficiently treat the film at lower temperatures. For example, in a conventional nitrogen anneal, the temperature may need to be performed at temperatures in excess of 600° C. to treat the deposited material. In embodiments, the post-deposition treatment may be performed at a semiconductor processing chamber, pedestal, or substrate 405 temperature greater than or about 250° C., and in some embodiments at a temperature that is greater than or about 300° C., greater than or about 320° C., greater than or about 340° C., greater than or about 360° C., greater than or about 380° C., greater than or about 400° C., greater than or about 420° C., greater than or about 440° C., greater than or about 460° C., greater than or about 480° C., greater than or about 500° C., greater than or about 520° C., greater than or about 540° C., greater than or about 560° C., greater than or about 580° C., or more. However, thermal budget constraints may require the semiconductor processing chamber, the pedestal, or the substrate 405 to be maintained at lower temperatures during the post-deposition treatment. Accordingly, in some embodiments, the semiconductor processing chamber, the pedestal, or the substrate 305 may be maintained at a temperature less than or about 600° C., and in some embodiments may be maintained at a temperature that is less than or about 580° C., less than or about 560° C., less than or about 540° C., less than or about 520° C., less than or about 500° C., or less.

In embodiments, the post-deposition treatment may be performed at high pressures than those during deposition of the silicon-containing material 420, the semiconductor processing chamber may be maintained at any pressure suitable for forming silicon-containing material. For example, a pressure within the semiconductor processing chamber is maintained at greater than or about 400 Torr, and in some embodiments may be maintained at a pressure that is greater than or about 420 Torr, greater than or about 440 Torr, greater than or about 460 Torr, greater than or about 480 Torr, greater than or about 500 Torr, greater than or about 520 Torr, greater than or about 540 Torr, greater than or about 560 Torr, greater than or about 580 Torr, greater than or about 600 Torr, greater than or about 620 Torr, greater than or about 640 Torr, greater than or about 660 Torr, greater than or about 680 Torr, greater than or about 700 Torr, greater than or about 720 Torr, greater than or about 740 Torr, greater than or about 760 Torr, or more.

The present technology may reduce or greatly reduce both the average roughness and the range of roughness of the silicon-containing material 420. For example, the hydrogen radicals produced may also improve surface roughness conditions by interacting with silicon-containing precursors during the deposition. Additionally, the post-deposition treatment may modify a surface of the film by reorganizing bonds to reduce surface roughness conditions. In embodiments, the post-deposition treatment may increase Si—O bonding in the silicon-containing material 420 by greater than or about 3 at. %, such as greater than or about 4 at. %, greater than or about 5 at. %, greater than or about 6 at. %, greater than or about 7 at. %, greater than or about 8 at. %, or more.

By producing silicon-containing materials according to embodiments of the present technology, hardness and modulus of the silicon-containing material may be higher than would otherwise occur with conventional PECVD deposition methods. For example, in some embodiments, the present technology may produce materials characterized by a Young's modulus of greater than or about 60 Gpa, such as greater than or about 65 Gpa, greater than or about 70 Gpa, greater than or about 75 Gpa, greater than or about 80 Gpa, greater than or about 85 Gpa, greater than or about 90 Gpa, or more.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a material” includes a plurality of such materials, and reference to “the precursor” includes reference to one or more precursors and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a silicon-containing precursor to a processing region of a semiconductor processing chamber, wherein a substrate is housed within the processing region of the semiconductor processing chamber;
providing a hydrogen-containing precursor to the processing region;
generating plasma effluents of the silicon-containing precursor and plasma effluents of the hydrogen-containing precursor in the processing region, wherein the plasma effluents are generated at a frequency greater than 15 MHz; and
depositing a silicon-containing material on the substrate.

2. The semiconductor processing method of claim 1, wherein the silicon-containing precursor comprises tetraethyl orthosilicate (TEOS).

3. The semiconductor processing method of claim 1, wherein the hydrogen-containing precursor comprises less than or about 5% of a total flow of precursors provided to the processing region.

4. The semiconductor processing method of claim 1, wherein a plasma power is maintained at less than or about 1000 W while generating plasma effluents of the silicon-containing precursor and plasma effluents of the hydrogen-containing precursor.

5. The semiconductor processing method of claim 1, wherein a temperature in the semiconductor processing chamber is maintained at less than or about 600° C. during the method.

6. The semiconductor processing method of claim 1, wherein a pressure in the semiconductor processing chamber is maintained at less than or about 30 Torr during the method.

7. The semiconductor processing method of claim 1, further comprising:
performing a post-deposition treatment on the silicon-containing material.

8. The semiconductor processing method of claim 7, wherein performing the post-deposition treatment increases an oxygen content in the silicon-containing material.

9. The semiconductor processing method of claim 7, wherein the post-deposition treatment comprises exposing the silicon-containing material to ultraviolet light.

10. The semiconductor processing method of claim 7, wherein the post-deposition treatment comprises annealing the silicon-containing material in the presence of a second hydrogen-containing precursor, a nitrogen-containing precursor, or an oxygen-containing precursor.

11. A semiconductor processing method comprising:
providing a silicon-containing precursor to a processing region of a semiconductor processing chamber, wherein a substrate is housed within the processing region of the semiconductor processing chamber;
generating plasma effluents of the silicon-containing precursor in the processing region;
depositing a silicon-containing material on the substrate; and
performing a post-deposition treatment on the silicon-containing material, wherein performing the post-deposition treatment increases an oxygen content in the silicon-containing material.

12. The semiconductor processing method of claim 11, wherein the substrate defines one or more features.

13. The semiconductor processing method of claim 11, wherein the plasma effluents are generated at a frequency greater than 15 MHz.

14. The semiconductor processing method of claim 11, further comprising:
providing a hydrogen-containing precursor to the processing region.

15. The semiconductor processing method of claim 14, wherein the hydrogen-containing precursor comprises molecular hydrogen (H₂).

16. The semiconductor processing method of claim 11, wherein the post-deposition treatment comprises exposing the silicon-containing material to ultraviolet light in the presence of an inert precursor or an oxygen-containing precursor.

17. The semiconductor processing method of claim 3, wherein the post-deposition treatment comprises annealing the silicon-containing material at a temperature less than or about 600° C.

18. A semiconductor processing method comprising:
providing a silicon-containing precursor to a processing region of a semiconductor processing chamber, wherein a substrate is housed within the processing region of the semiconductor processing chamber;
providing a hydrogen-containing precursor to the processing region;
generating plasma effluents of the silicon-containing precursor and plasma effluents of the hydrogen-containing precursor in the processing region, wherein the plasma effluents are generated at a frequency greater than 15 MHz;
depositing a silicon-containing material on the substrate; and
performing a post-deposition treatment on the silicon-containing material, wherein performing the post-deposition treatment increases an oxygen content in the silicon-containing material.

19. The semiconductor processing method of claim 18, wherein performing the post-deposition treatment decreases a hydrogen content in the silicon-containing material.

20. The semiconductor processing method of claim 18, further comprising:
halting a flow of the silicon-containing precursor and a flow of the hydrogen-containing precursor prior to performing the post-deposition treatment.
